(19) United States
(12) Patent Application Publication
(10) Pub. No.: US 2020/0257155 A1
(43) Pub. Date: Aug. 13, 2020

(54) DISPLAY DEVICE AND CONTROL METHOD THEREOF

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Xuerong WANG, Beijing (CN); Haiwei SUN, Beijing (CN); Caizheng ZHANG, Beijing (CN); Jianan WANG, Beijing (CN)

(21) Appl. No.: 15/773,642

(22) PCT Filed: Sep. 25, 2017
(86) PCT No.: PCT/CN2017/103149

§ 371 Date: May 4, 2018

(30) Foreign Application Priority Data
Jan. 12, 2017 (CN) 201710022953.1

(51) Int. Cl. G02F 1/137; G02F 1/133; H01L 27/32

(52) U.S. Cl. CPC G02F 1/13781; G02F 2001/13756; H01L 27/3232; G02F 1/13306

(57) ABSTRACT

A display device and a control method thereof are provided, which relate to the field of display technologies and can realize switching between viewing modes for the display device. The display device includes a peep-proof display module including a display panel and a peep-proof structure, and further includes a bistable liquid crystal cell having two stable states of a transmissive state and a scattering state. The bistable liquid crystal cell is disposed at the light exit side of the peep-proof structure.

### RELATED APPLICATION

The present application is the U.S. national phase entry of PCT/CN2017/103149, with an international filling date of Sep. 25, 2017, which claims the benefit of Chinese Patent Application No. 201710022953.1, filed on Jan. 12, 2017, the entire disclosure of which is incorporated herein by reference.

### TECHNICAL FIELD

The present disclosure relates to the field of display technologies, and particularly to a display device and a control method thereof.

### BACKGROUND

At present, in order to protect trade secrets and personal privacy, a peep-proof sheet is generally applied to a display device so that the viewing angle for the display device is about 60°. That is, if the display screen of the display device is viewed from areas outside the area formed by two lines at an angle of 30° to the central normal line, respectively, only the dark screen can be seen, so information displayed by the display screen can only be read by a user facing the center portion of the screen. In this way, the loss caused by information leakage can be avoided.

However, the above display device added with the peep-proof sheet will cause the viewing angle for the display device to be always limited to about 60°. When information displayed by the display device needs to be shown to multiple persons, it cannot be realized by the above display device, thereby causing some inconvenience to the user who uses the display device.

### SUMMARY

Embodiments of the present disclosure provide a display device and a control method thereof, which can realize switching between viewing modes for the display device.

In an aspect, there is provided a display device comprising: a peep-proof display module, the peep-proof display module comprising a display panel and a peep-proof structure; and a bistable liquid crystal cell, the bistable liquid crystal cell having stable states of transmissive state and a scattering state. The bistable liquid crystal cell is disposed at a light exit side of the peep-proof structure.

In some embodiments, the peep-proof structure is a peep-proof sheet.

In some embodiments, the display panel is a self-luminous display panel, and the peep-proof sheet is disposed at a light exit side of the display panel.

Alternatively, in another embodiment, the display panel is a passive light emitting display panel, and the peep-proof sheet is disposed at a light incident side of the display panel.

Further, in some embodiments, the peep-proof sheet is located between a backlight source used for the passive light emitting display panel and the passive light emitting display panel.

In some embodiments, the display panel is a passive light emitting display panel, and the peep-proof sheet is disposed at a light exit side of the display panel.

In some embodiments, the passive light emitting display panel is located between the peep-proof sheet and a backlight source used for the passive light emitting display panel.

In some embodiments, the display panel is a passive light emitting display panel, and the peep-proof structure is a backlight source that is used for a passive light emitting display panel and emits collimated backlight with a collimation degree of ±30 degrees.

In some embodiments, the self-luminous display panel comprises an OLED display panel.

In some embodiments, the passive light emitting display panel comprises a LCD display panel.

In some embodiments, the bistable liquid crystal cell includes a first substrate, a second substrate, and a bistable liquid crystal disposed between the first substrate and the second substrate; the first substrate and the second substrate being provided with a plurality of transparent electrodes, respectively.

In some embodiments, the bistable liquid crystal is a smectic liquid crystal.

In some embodiments, the display device further comprises a switching button used to control the bistable liquid crystal cell to exhibit a transmissive state or a scattering state.

Another embodiment of the present disclosure provides a control method for the display device according to any of the embodiments described above, comprising:

in a shared display mode, controlling the bistable liquid crystal cell to exhibit the transmissive state;

in a peep-proof display mode, controlling the bistable liquid crystal cell to exhibit the scattering state.

Further, in some embodiments, in the shared display mode, the switching button is operated to make the bistable liquid crystal cell exhibit the transmissive state; in the peep-proof display mode, the switching button is operated to make the bistable liquid crystal cell exhibit the scattering state.

### BRIEF DESCRIPTION OF DRAWINGS

In order to illustrate the technical solutions of embodiments of the disclosure more clearly, the drawings required for description of the embodiments will be briefly described below. The drawings in the description below are merely some embodiments of the invention. For those ordinarily skilled in the art, other drawings may also be obtained based on these drawings without inventive efforts.

FIG. 1 is a schematic structural diagram of a display device provided by an embodiment of the disclosure;

FIG. 2 is a schematic structural diagram of a display device provided by another embodiment of the disclosure;

FIG. 3 is a schematic structural diagram of a display device provided by another embodiment of the disclosure;

FIG. 4 is a schematic structural diagram of a display device provided by a further embodiment of the disclosure;

FIG. 5 is a schematic structural diagram of a display device provided by a further embodiment of the disclosure;

FIG. 6 is a schematic structural diagram of a display device provided by yet another embodiment of the disclosure;

FIG. 7 and FIG. 8 are schematic diagrams illustrating a principle of changes of the state of the liquid crystal in a bistable liquid crystal cell provided by an embodiment of the disclosure;

FIG. 9 is a diagram showing comparisons between the viewing angles and the display brightnesses of a conventional peep-proof display device and a conventional display device;

FIG. 10 is a diagram showing comparisons between the viewing angles and the display brightnesses of a bistable display device and a conventional display device;

FIG. 11 is a diagram showing comparisons between the viewing angles and the display brightnesses in two display modes of a display device provided by an embodiment of the disclosure.

### REFERENCE NUMERALS

11—display panel; 12—peep-proof structure; 13—bistable liquid crystal cell; 131—first substrate; 132—second substrate; 133—bistable liquid crystal; 134—transparent electrode; 14—backlight source; 15—peep-proof sheet; 16—narrow-viewing angle backlight source

### DETAILED DESCRIPTION

The technical solutions in embodiments of the present disclosure will be described below in a clear and complete manner with reference to the accompanying drawings. The described embodiments are merely a part of possible embodiments of the invention, rather than all of them. All other embodiments obtained by those ordinarily skilled in the art based on the embodiments of the disclosure without inventive efforts shall fall within the scope of the invention.

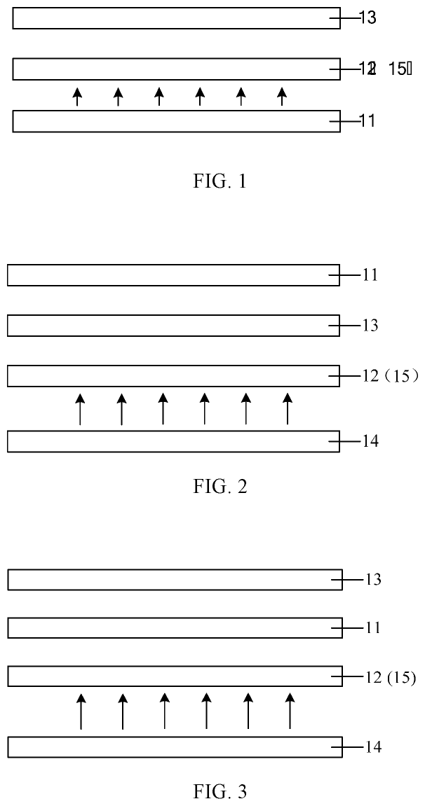

An embodiment of the disclosure provides a display device, as shown in FIGS. 1 to 6, comprising a peep-proof display module and a bistable liquid crystal cell 13. The peep-proof display module comprises a display panel 11 and a peep-proof structure 12. The bistable liquid crystal cell 13 has two stable states: a transmissive state and a scattering state, and it is disposed at a light exit side of the peep-proof structure 12.

The two stable states of the bistable liquid crystal cell 13 may depend on the magnitude of the voltage applied to the bistable liquid crystal. When the bistable liquid crystal cell 13 is in a transmissive state, light exiting from the peep-proof structure 12 has a small refraction angle in the bistable liquid crystal cell 13 or propagates along a straight line. That is, the influence by the bistable liquid crystal cell 13 on the viewing angle of the display device at that time can basically be ignored, the viewing angle of the display device is still small, the display device is in a peep-proof display mode, and the image displayed by the display device can only be read by the viewer facing the center portion of the screen. When the bistable liquid crystal cell 13 is in a scattering state, light exiting from the peep-proof structure 12 is scattered in the bistable liquid crystal cell 13. Therefore, the viewing angle of the display device is large at this time, and the display device is in a shared display mode. In this case, the image displayed by the display device can be seen by viewers in multiple directions, so that information displayed by the display device can be shown to multiple persons.

It is to be noted that the specific structure of the bistable liquid crystal cell 13 and the type of liquid crystals therein are not limited herein, as long as the bistable liquid crystal cell 13 can present two stable states, i.e. a transmissive state and a scattering state, according to the voltage applied to the bistable liquid crystal cell 13.

In addition, the above-mentioned display panel may be a self-luminous display panel or a passive light emitting display panel. Accordingly, the arrangements of the peep-proof structure 12 and the bistable liquid crystal cell 13 may vary according to the type of the display panel.

For the display device provided by the embodiment of the disclosure, by arranging the bistable liquid crystal cell 13 at the light exit side of the peep-proof structure of the peep-proof display module, two stable states of the bistable liquid crystal cell 13 can be utilized to get the display device in a peep-proof display mode and a shared display mode, respectively, thereby enabling the display device to achieve switching between viewing modes.

In some embodiments, as shown in FIGS. 1 to 4, the peep-proof structure 12 is a peep-proof sheet 15.

It is to be noted that the specific structure of the peep-proof sheet 15 is not limited herein, as long as the viewing angle of the display device can be limited within a relatively small range by means of the peep-proof structure 12. For example, the peep-proof structure may be a shutter-type peep-proof sheet 15.

Further, the display panel 11 may be a self-luminous display panel or a passive light emitting display panel. In case the display panel 11 is a self-luminous display panel, the peep-proof sheet 15 is disposed at the light exit side of the display panel 11. If the display panel 11 is a passive light emitting display panel, the peep-proof sheet 15 is disposed at the light incident side or the light exit side of the display panel 11.

As shown in FIG. 1, the display panel 11 is a self-luminous display panel, the peep-proof sheet 15 is disposed at the light exit side of the display panel 11, and the bistable liquid crystal cell 13 is disposed at the light exit side of the peep-proof sheet 15.

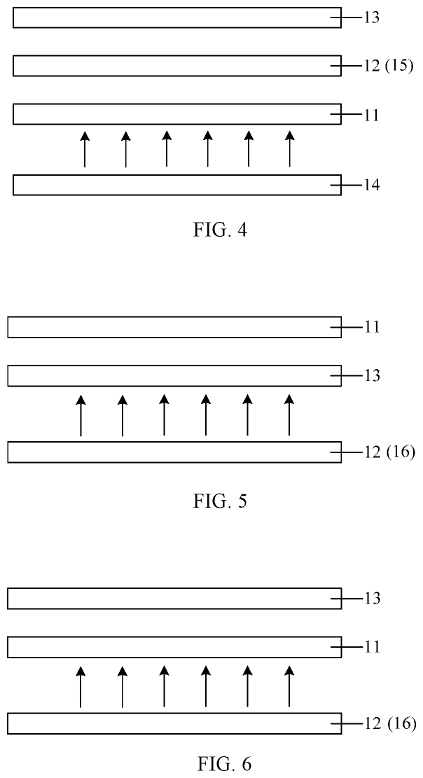

As shown in FIGS. 2 to 4, in another embodiment, the display panel 11 is a passive light emitting display panel, and the display device further comprises a backlight source 14. In the embodiment shown in FIG. 2, the peep-proof sheet 15 may be disposed at the light incident side of the display panel 11, and the bistable liquid crystal cell 13 is disposed between the peep-proof sheet 15 and the display panel 11. Alternatively, as shown in FIG. 3, the peep-proof sheet 15 may be disposed at the light incident side of the display panel 11, and the bistable liquid crystal cell 13 may be disposed at the light exiting side of the display panel 11. In the embodiment shown in FIG. 4, the peep-proof sheet 15 may be disposed at the light exit side of the display panel 11, and the bistable liquid crystal cell 13 may be disposed at the light exit side of the peep-proof sheet 15.

In some embodiments, the self-luminous display panel is an OLED (Organic Light-Emitting Diode) display panel. The OLED display panel has the advantages such as large viewing angle range, uniform image quality, fast response speed, simple driving, and the like.

In some embodiments, the passive light emitting display panel is a LCD (Liquid Crystal Display) panel. The LCD panel has the advantages such as small size, low power consumption, little radiation, and the like.

In another embodiment, as shown in FIGS. 5 to 6, the peep-proof structure 12 is a narrow-viewing angle backlight source 16, and based on this, the display panel 11 is a passive light emitting display panel. The “narrow-viewing angle backlight source” referred to herein refers to a backlight source which is used for a passive light emitting display panel and whose emitted light has been collimated. In an embodiment, the peep-proof structure 12 is a backlight source whose emitted light has a collimation degree of ±30 degrees, that is, the divergence angle of light emitted from the backlight source relative to parallel light is within 30 degrees.

The display panel 11 and the bistable liquid crystal cell 13 are located at the light exit side of the narrow-viewing angle backlight source 16. Specifically, as shown in FIG. 5, the bistable liquid crystal cell 13 may be located between the narrow-viewing angle backlight source 16 and the display panel 11. Alternatively, as shown in FIG. 6, the bistable liquid crystal cell 13 is located at the light exit side of the display panel 11. Using the narrow-viewing angle backlight source 16 as the peep-proof structure 12 can reduce the cost of the entire display device.

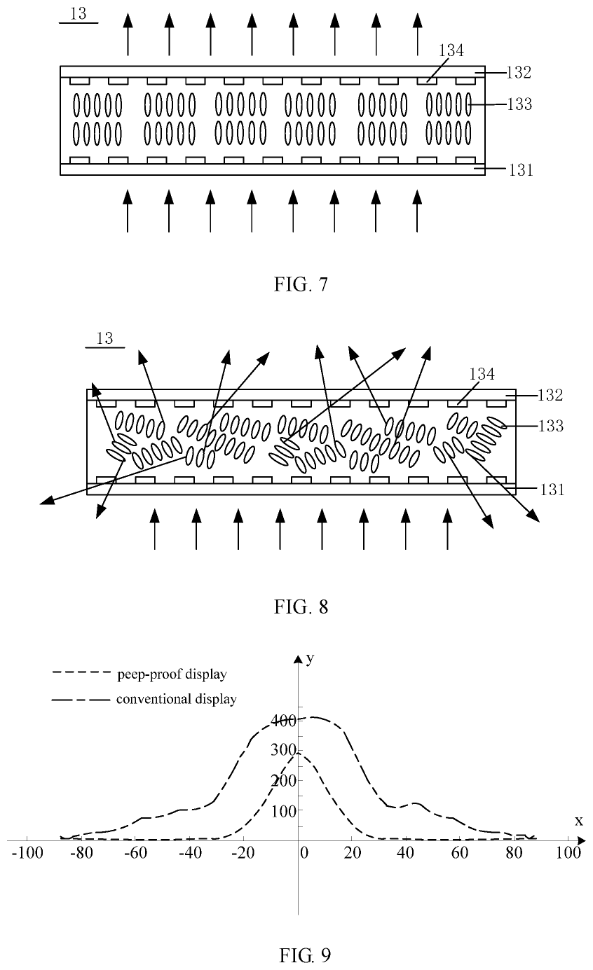

In an embodiment of the disclosure, as shown in FIG. 7, the bistable liquid crystal cell includes a first substrate 131, a second substrate 132, and a bistable liquid crystal 133 between the first substrate 131 and the second substrate 132. The first substrate 131 and the second substrate 132 are provided with a plurality of transparent electrodes 134, respectively. The material of the transparent electrode 134 may be indium tin oxide (ITO) or indium zinc oxide (IZO).

In an example, the bistable liquid crystal 133 is a smectic liquid crystal. Smectic liquid crystals have a two-dimensionally ordered characteristic of flowing in layers and not flowing between layers, which can be used for large-scale display.

The operating principle of the bistable liquid crystal cell 13 will be briefly described below. As shown in FIG. 7, when the difference between the voltage applied to the transparent electrode 134 on the first substrate 131 and the voltage applied to the transparent electrode 134 on the second substrate 132 is less than a first threshold, the liquid crystal molecules inside the bistable liquid crystal cell 13 are in a regular arrangement to form a transmissive state. As shown in FIG. 8, when the difference between the voltage applied to the transparent electrode 134 on the first substrate 131 and the voltage applied to the transparent electrode 134 on the second substrate 132 is greater than a second threshold, the liquid crystal molecules inside the bistable liquid crystal cell 13 are in disorder to form a scattering state. If the difference between the voltage applied to the transparent electrode 134 on the first substrate 131 and the voltage applied to the transparent electrode 134 on the second substrate 132 is between the first threshold and the second threshold, the liquid crystal molecules inside the bistable liquid crystal cell 13 are in a state between the transmissive state and the scattering state. At this time, after the voltage applied to the bistable liquid crystal cell 13 is cancelled, the bistable liquid crystal cell 13 would maintain the state when the voltage is applied due to the interaction force between the liquid crystal molecules, and a stable state is formed.

In an example where the bistable liquid crystal 133 is a smectic liquid crystal, the first threshold may be 5V, and the second threshold may be 30V.

It is to be noted that the number of transparent electrodes 134 provided on the first substrate 131 and the second substrate 132 is not limited, which may be reasonably determined according to the resolution that needs to be achieved when the display device performs displaying. Here, the resolution of the display device is related to the number of transparent electrodes 134. The greater the number of transparent electrodes 134 is, the higher the resolution achieved by the display device is.

In the embodiment, since the first substrate 131 and the second substrate 132 are provided with a plurality of transparent electrodes 134, the voltages applied to the transparent electrodes 134 on the first substrate 131 and the second substrate 132 can be controlled to make the bistable liquid crystal cell 13 exhibit a transmissive state or a scattering state.

The viewing angle and the display brightness of the display device proposed by the embodiments of the disclosure will be illustrated below by several experiments.

FIG. 9 is a diagram showing comparisons between the viewing angles and the display brightness of a peep-proof display device including the peep-proof display module while not including the bistable liquid crystal cell 13 and a conventional display device not including the peep-proof structure 12 and the bistable liquid crystal cell 13, where the x-axis represents the visible angle and the y-axis shows the display brightness.

As can be seen from FIG. 9, the viewing angle range of the peep-proof display device is significantly smaller than that of the conventional display device. Since the peep-proof display device is added with a peep-proof sheet, the loss of light is increased, so that the display brightness is reduced.

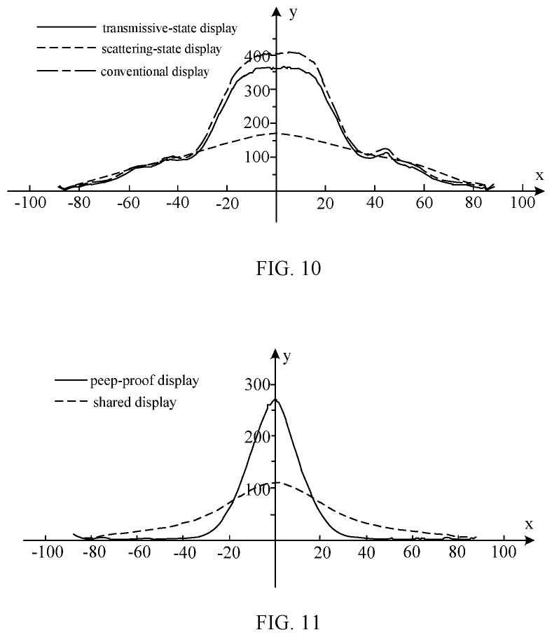

FIG. 10 is a diagram showing comparisons between the viewing angles and the display brightness of a bistable display device including the bistable liquid crystal cell 13 while not including the peep-proof structure 12 and a conventional display device not including the peep-proof structure 12 and the bistable liquid crystal cell 13, where the x-axis represents the visible angle and the y-axis represents the display brightness.

As can be seen from FIG. 10, regardless of whether the bistable display device is in a transmissive-state display mode or a scattering-state display mode, the viewing angle range thereof is substantially unchanged relative to the conventional display device. In case the bistable display device is in a transmissive-state display mode, the trend of change in display brightness of the bistable display device with the viewing angle is basically the same as the trend of change in display brightness of the conventional display device with the viewing angle. When the bistable display device is in a scattering-state display mode, the display brightness of the bistable display device gradually decreases as the viewing angle increases.

FIG. 11 is a diagram showing comparisons between the viewing angles and the display brightnesses of the display device provided by an embodiment of the disclosure when it is in a peep-proof display mode and a shared display mode, respectively, where the x-axis represents the visible angle, and the y-axis represents the display brightness.

As can be seen from FIG. 11, when the display device provided by the embodiment of the disclosure is in a peep-proof display mode, it has a smaller viewing angle and a higher display brightness, when the display device is in a shared display mode, it has a larger viewing angle and a lower display brightness.

As can be seen from the above, if the display device according to the embodiment of the disclosure is in a peep-proof display mode, the viewing angle range and the brightness thereof are basically the same as those of the peep-proof display device including the peep-proof display module while not including the bistable liquid crystal cell 13. When the display device according to the embodiment of the disclosure is in a shared display mode, the viewing angle range and the brightness thereof are basically the same as those of the bistable display device including the bistable liquid crystal cell 13 while not including the peep-proof structure 12 in a scattering-state display mode.

That is, for the embodiment of the disclosure, the display device is compatible with two display modes by combining the peep-proof display module with the bistable liquid crystal cell 13, and the display effects thereof in the two display modes are comparable to those of the peep-proof display device including the peep-proof display module while not including the bistable liquid crystal cell 13, and the bistable display device including the bistable liquid crystal cell 13 while not including the peep-proof structure 12, respectively.

In another embodiment, the display device further comprises a switching button used to control the bistable liquid crystal cell to be in a transmissive state or a scattering state.

In some embodiments, the stable states of the bistable liquid crystal cell 13 can be controlled by means of the switching button according to the user's requirements. When the display device is required to perform peep-proof displaying, the bistable liquid crystal cell 13 can be controlled to be in a transmissive state by the switching button; when the display device is required to perform shared displaying, the bistable liquid crystal cell 13 can be controlled to be in a scattering state by the switching button.

A further embodiment of the disclosure provides a control method for the display device described above, comprising: controlling the bistable liquid crystal cell to exhibit a transmissive state in a shared display mode; and controlling the bistable liquid crystal cell to exhibit a scattering state in a peep-proof display mode.

When the bistable liquid crystal cell includes a plurality of transparent electrodes 134 disposed on the first substrate 131 and the second substrate 132, the voltage applied to the bistable liquid crystal 133 is controlled by inputting a voltage signal to the plurality of transparent electrodes 134 on the first substrate 131 and the second substrate 132, respectively, thereby controlling the display device to be in a shared display mode or a peep-proof display mode.

In an embodiment, in the shared display mode, the switching button is operated to make the bistable liquid crystal cell 13 exhibit a transmissive state; in the peep-proof display mode, the switching button is operated to make the bistable liquid crystal cell 13 exhibit a scattering state.

By way of example, the switching button is pressed to cause the difference between the voltage of the transparent electrodes 134 on the first substrate 131 and the voltage of the transparent electrodes 134 on the second substrate 132 to be greater than the second threshold, so that the bistable liquid crystal cell 13 exhibits a scattering state, which causes the display device to be in a shared display mode. The switching button is pressed again to cause the difference between the voltage applied to the transparent electrodes 134 on the first substrate 131 and the voltage applied to the transparent electrodes 134 on the second substrate 132 to be less than the first threshold, so that the bistable liquid crystal cell 13 exhibits a transmissive state, which makes the display device in a peep-proof display mode.

In an embodiment, a voltage output circuit is integrated in a driving IC of the display device, so as to control the magnitude of the voltage applied to the bistable liquid crystal 133. Or high voltage and low voltage pins are reserved on the mainboard of the display device to control the magnitude of the voltage applied to the bistable liquid crystal 133.

With the embodiments of the disclosure, the stable states of the bistable liquid crystal cell 13 can be controlled by means of the switching button according to the user's requirements. When the display device is required to be in a peep-proof display mode, the bistable liquid crystal cell 13 can be controlled to be in a transmissive state by the switching button. When the display device is required to be in a shared display mode, the bistable liquid crystal cell 13 can be controlled to be in a scattering state by the switching button.

What have been stated above are only part of specific embodiments of the invention, but the protection scope of the invention is not so limited. Variations or replacements that can be easily conceived by any skilled person familiar with this technical field within the technical scope revealed by the disclosure shall be encompassed within the scope of the invention. Thus, the protection scope of the invention shall be based on the scope of the appended claims.

1. A display device comprising:
a peep-proof display module, the peep-proof display module including a display panel and a peep-proof structure; and
a bistable liquid crystal cell, the bistable liquid crystal cell having two stable states of a transmissive state and a scattering state;
wherein the bistable liquid crystal cell is disposed at a light exit side of the peep-proof structure.

2. The display device according to claim 1, wherein the peep-proof structure is a peep-proof sheet.

3. The display device according to claim 2, wherein the display panel is a self-luminous display panel, and the peep-proof sheet is disposed at a light exit side of the display panel.

4. The display device according to claim 2, wherein the display panel is a passive light emitting display panel, and the peep-proof sheet is disposed at a light incident side of the display panel.

5. The display device according to claim 4, wherein the peep-proof sheet is located between a backlight source used for the passive light emitting display panel and the passive light emitting display panel.

6. The display device according to claim 2, wherein the display panel is a passive light emitting display panel, and the peep-proof sheet is disposed at a light exit side of the display panel.

7. The display device according to claim 6, wherein the passive light emitting display panel is located between the peep-proof sheet and a backlight source used for the passive light emitting display panel.

8. The display device according to claim 1, wherein the display panel is a passive light emitting display panel, and the peep-proof structure is a backlight source that is used for the passive light emitting display panel and emits collimated backlight with a collimation degree of about ±30 degrees.

9. The display device according to claim 3, wherein the self-luminous display panel comprises an OLED display panel.

10. The display device according to claim 4, wherein the passive light emitting display panel comprises a LCD display panel.

11. The display device according to claim 1, wherein the bistable liquid crystal cell includes a first substrate, a second substrate, and a bistable liquid crystal between the first substrate and the second substrate,
wherein the first substrate and the second substrate are provided with a plurality of transparent electrodes, respectively.

12. The display device according to claim 11, wherein the bistable liquid crystal is a smectic liquid crystal.

13. The display device according to claim 1, wherein the display device further comprises a switching button, which is used to control the bistable liquid crystal cell to exhibit the transmissive state or the scattering state.

14. A control method for a display device comprising:
a peep-proof display module, the peep-proof display module including a display panel and a peep-proof structure; and
a bistable liquid crystal cell, the bistable liquid crystal cell having two stable states of a transmissive state and a scattering state;
wherein the bistable liquid crystal cell is disposed at a light exit side of the peep-proof structure,
the method comprising:
in a shared display mode, controlling the bistable liquid crystal cell to exhibit the transmissive state;
in a peep-proof display mode, controlling the bistable liquid crystal cell to exhibit the scattering state.

15. The control method according to claim 14, wherein in the shared display mode, the switching button is operated to make the bistable liquid crystal cell exhibit the transmissive state,
in the peep-proof display mode, the switching button is operated to make the bistable liquid crystal cell exhibit the scattering state.

16. The display device according to claim 6, wherein the passive light emitting display panel comprises a LCD display panel.

17. The control method according to claim 14, wherein the peep-proof structure is a peep-proof sheet.

18. The control method according to claim 17, wherein the display panel is a self-luminous display panel, and the peep-proof sheet is disposed at a light exit side of the display panel.

19. The control method according to claim 17, wherein the display panel is a passive light emitting display panel, and the peep-proof sheet is disposed at a light incident side of the display panel.

20. The control method according to claim 19, wherein the peep-proof sheet is located between a backlight source used for the passive light emitting display panel and the passive light emitting display panel.
